(19) United States
(12) Patent Application Publication
(10) Pub. No.: US 2001/0044911 A1
(43) Pub. Date: Nov. 22, 2001

(54) Information processing method, information processing apparatus and memory medium

(75) Inventor: Junichi Iijima, Kawasaki (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: FUJITSU LIMITED, Kawasaki (JP)

(21) Appl. No.: 09/880,049

(22) Filed: Jun. 14, 2001

Related U.S. Application Data
(63) Continuation of application No. PCT/JP99/02641, filed on May 20, 1999.

(30) Foreign Application Priority Data
Dec. 15, 1998 (JP) 10-356521

(51) Int. Cl. H03K 19/003

(52) U.S. Cl. 714/15

(57) ABSTRACT

Purpose is to provide an information processing method, an information processing apparatus and a memory medium that enable an easy and accurate data recovery when data was destroyed, relative to the information processing method, the information processing apparatus and the memory medium that manage a transaction log by an upper apparatus and a terminal apparatus. The transaction log information input to POS terminal apparatus 12 is transmitted to a server controller 11 every time the transaction occurs. The server controller 11 stores the transaction log information. When a fault occurs at the POS terminal apparatus 12, upon repairing the fault, the POS terminal 12 issues a recovery instruction to the server controller 11. In this manner, the present day transaction log information and the previous day hard total information are retrieved from the server controller 11. Based on the transaction log information and the hard total information obtained, the present day transaction log information and its hard total information are restored to bring the POS apparatus 12 back to where it stood before the fault occurrence.

### FIELD OF THE INVENTION

The present invention generally relates to an information processing method, an information processing apparatus, and a memory medium, and particularly relates to an information processing method, an information processing apparatus, and a memory medium that manage a transaction log by an upper apparatus and a terminal apparatus.

Recently, a POS system has been introduced in convenience stores and the like, thereby managing affairs relating to merchandize, sales figures and the like.

The POS system includes a host computer installed in a head office and server controllers and POS terminal apparatuses provided in the stores.

At each of the stores, a plurality of the POS terminal apparatuses are typically connected to the server controller.

Each of the POS terminal apparatuses stores information such as a scan-input merchandise code, a sales amount, time, customer information and the like as transaction log information for each transaction. Further, each of the POS terminal apparatuses generates and stores hard total information by adding up the transaction information one after another. The generated hard total information is transmitted to the server controller upon settlement.

Further, the server controller centrally controls the transaction log information and the total information of the plurality of POS terminal apparatuses which are connected thereto.

### BACKGROUND TECHNOLOGY

In a conventional POS system, settlements of a POS terminal are made at predetermined hours. The settlement process transmits the hard total information generated based on the transaction log information from POS terminals to the server controller at constant intervals, for example, once in every 24 hours.

If the replacement of a hard drive or the like takes place due to a trouble in the POS terminal, the transaction log information and the hard total information stored in the POS terminal will be erased, causing a discrepancy in information such as transaction serial number and the like between the server controller and the POS terminal. Therefore, there is a need to recover the transaction log information and the hard total information that are stored in the POS terminal prior to the trouble.

Conventionally, data is manually entered from a printout of the transaction log information that has been printed for each transaction at the POS terminal in order to recover the transaction log information and the hard total information stored in the POS terminal prior to the trouble.

In the conventional POS terminals, when the replacement of the hard drive or the like takes place due to the trouble of the POS terminal, and the stored transaction log information and the hard total information are erased, data is manually input by referring to the transaction log information that is printed out for each transaction at the POS terminal, thereby recovering the transaction log information and the hard total information stored in the POS terminal prior to the trouble, creating a problem that it requires a lengthy time and is likely to cause input errors and the like.

The present invention is made in view of the points described above, and is aimed at providing an information processing method, an information processing apparatus, and a memory medium that provide easy and accurate data recovery when data is destroyed.

### DISCLOSURE OF THE INVENTION

According to the present invention, a terminal apparatus includes:

inputting means for inputting information;

total information generating means for generating total information that is a total of the information input by the inputting means;

storing means for storing the input information that is input by the inputting means and the total information generated by the total information generating means;

information transmitting means for transmitting the input information that is input by the inputting means to an upper apparatus for each and every input and transmitting the total information generated by the total information generating means to the upper apparatus at predetermined intervals;

input information transmission requesting means for requesting a transmission of the input information of the upper apparatus when a trouble occurs; and

recovering means for storing the input information that is input from the upper apparatus to the storing means when the input information is received from the upper apparatus, and for recovering the total information by totaling the input information that is input from the information apparatus.

The terminal apparatus in the present invention further includes:

storing means for storing the input information that is input by the terminal apparatus and transmitted to the upper apparatus and storing the total information which is a sum of the input information transmitted from the terminal apparatus at predetermined intervals; and

information transmitting means for transmitting the input information and the total information stored in the storing means to the terminal apparatus upon a request from the terminal apparatus.

The present invention enables a recovery of the terminal apparatus to a status immediately prior to a failure, when the terminal apparatus requests input information upon suffering of the failure, by recovering the input information through acquisition of the input information stored in the upper apparatus each time an information input occurs at the terminal apparatus, and by recovering the total information through acquisition of the total information which is obtained by totaling the input information at every predetermined interval in the terminal apparatus and stored in the upper apparatus.

### BRIEF DESCRIPTION OF THE DRAWINGS

FIG. 1 is a summary drawing of an embodiment of the present invention.

FIG. 2 is a block diagram of the server controller of the embodiment of the present invention.

FIG. 3 is a block diagram of the POS terminal apparatus of the embodiment of the present invention.

FIG. 4 shows a data structure of the transaction log information of the embodiment of the present invention.

FIG. 5 shows a data structure of the transaction header information of the embodiment of the present invention.

FIG. 6 shows a data structure of the transaction specification information of the embodiment of the present invention.

FIG. 7 shows a data structure of the transaction footer information of the embodiment of the present invention.

FIG. 8 shows a data structure of the hard total information of the embodiment of the present invention.

FIG. 9 shows a data structure of the journal hard total information of the embodiment of the present invention.

FIG. 10 shows a data structure of the journal hard total information of the embodiment of the present invention.

FIG. 11 shows a data structure of the journal hard total information of the embodiment of the present invention.

FIG. 12 shows a data structure of the journal hard total information of the embodiment of the present invention.

FIG. 13 shows a data structure of the POS settlement management information of the embodiment of the present invention.

FIG. 14 shows a data structure of the transaction log pointer management information of the embodiment of the present invention.

FIG. 15 is a process flowchart of the POS terminal apparatus during a normal process of the embodiment of the present invention.

FIG. 16 is a process flowchart of the server controller during a normal process of the embodiment of the present invention.

FIG. 17 is a process flowchart of the POS terminal apparatus for the settlement process of the embodiment of the present invention.

FIG. 18 is a process flowchart of the server controller for the settlement process of the embodiment of the present invention.

FIG. 19 is a process flowchart of the server controller for the recovery process of the embodiment of the present invention.

FIG. 20 is a process flowchart of the POS terminal apparatus for the recovery process of the embodiment of the present invention.

FIG. 21 describes operations during the normal process of the embodiment of the present invention.

FIG. 22 describes operations during the settlement process of the embodiment of the present invention.

FIG. 23 describes operations during the recovery process of the embodiment of the present invention.

FIG. 24 describes operations of the POS terminal apparatus during the recovery process of the embodiment of the present invention.

### DESCRIPTION OF THE BEST MODE IMPLEMENTATION

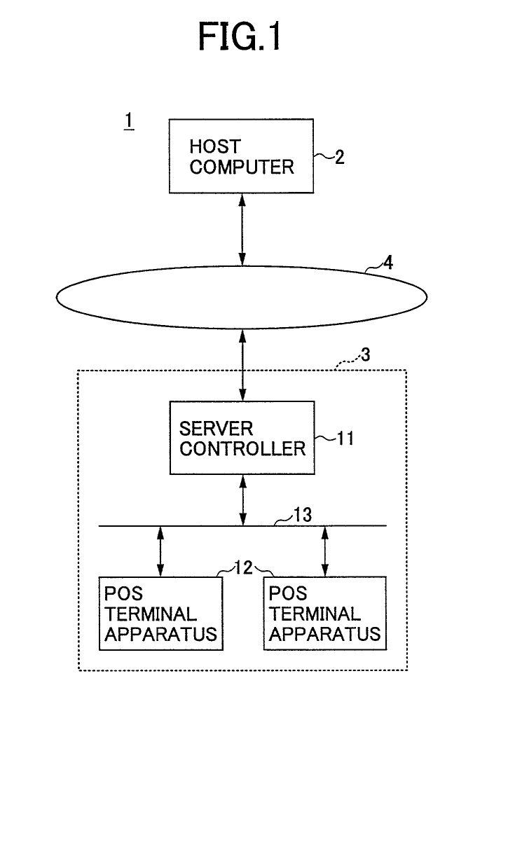

FIG. 1 shows an overview of the structure of an embodiment of the present invention.

A system 1 of this embodiment includes a host computer 2 and a POS apparatus 3 which are connected via a telephone line 4. The host computer 2 is provided at a head office and the POS apparatus 3 is provided in each store.

The POS apparatus 3 adds up transaction logs at each shop and transmits the sum to the host computer 2 via the telephone line 4. The host computer 2 adds up transaction logs from each store. The POS apparatus 3 generates a transaction log every time a transaction takes place. The POS apparatus 3 includes a sever controller 11 and POS terminal apparatuses 12 which are connected by a LAN circuit 13.

The server controller 11 is provided of a store office and the like, and adds up transaction logs supplied from the POS terminal apparatuses 12 via the LAN circuit 13.

The POS terminal apparatus 12 is provided at a cash register of the store, and reads bar codes or the like attached to purchased goods to obtain a sales total of each transaction, followed by supplying the transaction log to the server controller 11 via the LAN circuit 13.

In the following, a detailed description of the server controller 11 will be given.

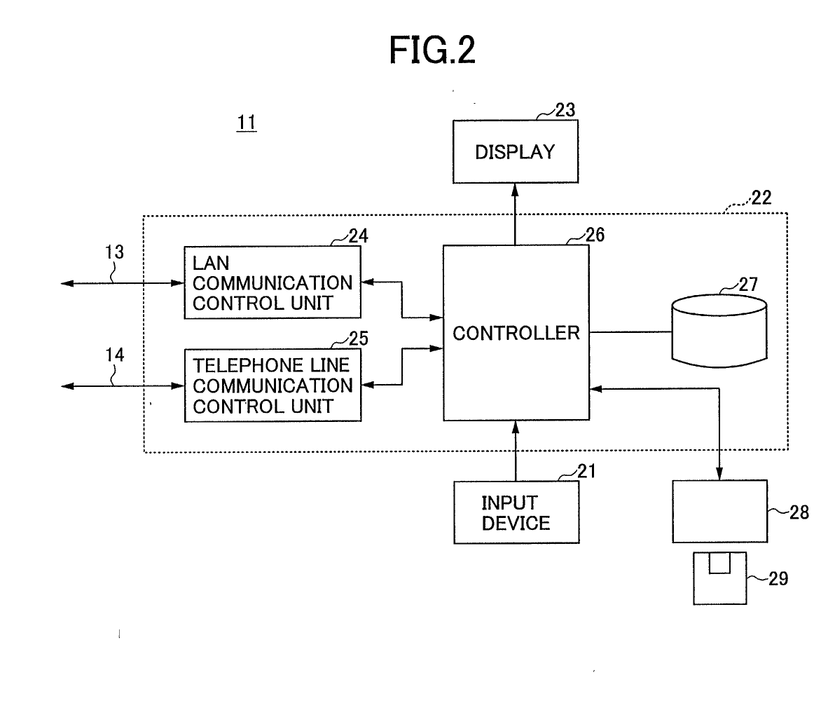

FIG. 2 is a block diagram of the server controller of the embodiment of the present invention.

The server controller 11 includes an input apparatus 21, a server controller core 22, a display 23 and an external memory apparatus 28.

The input apparatus 21 includes a mouse, a keyboard and the like and inputs instructions regarding a settlement process, a recovery process and the like to the server controller core 22 as will be described later.

The server controller core 22 includes a LAN communication control unit 24, a telephone line communication control unit 25, a control unit 26, and a memory unit 27. The LAN communication control unit 24 controls communication with the LAN circuit 13. The telephone line communication control unit 25 controls communication with the telephone line 4. The control unit 26 is connected to the LAN communication control unit 24, the telephone line communication control unit 25 and the memory unit 27, and executes a transaction log totaling process, a settlement process, a recovery process and the like based on a program memorized in advance.

The transaction log processed by the control unit 26 for totaling, settlement and recovery is mirror-memorized by the memory unit 27.

The external memory apparatus 28 is equipped with a replaceable memory medium 29. For example, the program described above is installed by the external memory apparatus 28 from the replaceable memory medium 29. Further, data that is processed by the control unit 26 using the above mentioned program is stored in the replaceable memory medium 29 by the external memory apparatus 28.

In the following, a detailed description of the POS terminal apparatus 12 will be given.

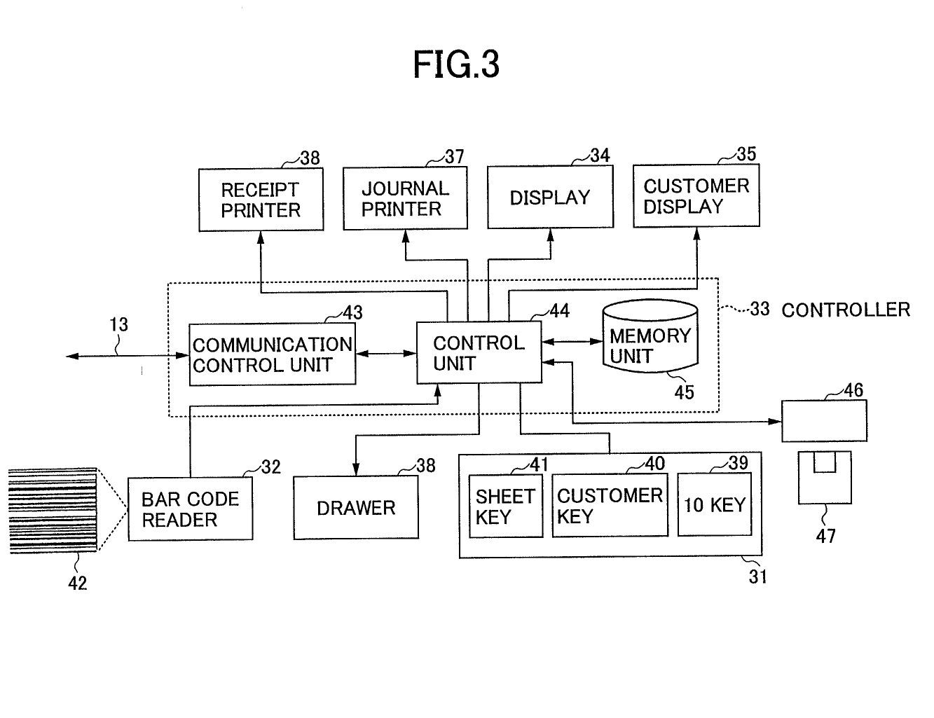

FIG. 3 is a block diagram of the POS terminal apparatus of the embodiment of the present invention.

The POS terminal apparatus 12 includes a keyboard 31, a bar code reader 32, a controller 33, a display 34, a customer display 35, a receipt printer 36, a journal display 37, a drawer 38 and an external memory apparatus 46 which are connected to the server controller 11 via the LAN circuit 13.

The keyboard 31 is operated when a code of purchased merchandize and a price amount thereof are manually input. The keyboard 31 includes a 10-key 39, a customer information key 40, and a sheet key 41. The 10-key 39 is used to input the merchandize code of merchandize purchased and a price amount thereof. The customer information key 40 is used to input customer information. The sheet key 41 is operated to activate preset operations.

The bar code reader 32 reads a bar code 42 that is attached to merchandize in advance. The merchandize code information read by operating the keyboard 31 or by the bar code reader 32 is supplied to the controller 33.

The controller 33 includes a communication control unit 43, a control unit 44 and a memory unit 45 and performs processes such as normal transactions, settlements and recoveries, as will be described later, the process result of which is transmitted to the server controller 11 via the LAN circuit 13. The communication control unit 43 controls communication with the server controller 11 via the LAN circuit 13. The control unit 44 executes the transaction process, the settlement process, the recovery process and the like based on the programs stored in the memory unit 45 and the process result is stored in the memory unit 45. Further, the control unit 44 is connected to the display 34, the customer display 35, the journal printer 37 and the receipt printer 38, thereby displaying the transaction result and controlling the printing.

The display 34 is provided to face a cashier, is controlled by the control unit 44, and displays a merchandize name, a unit price, a total price and the like that are input. The cashier can recognize the input merchandize name, the unit price, the total price of the input merchandize and the like by the display of the display 34. The customer display 35 is provided to face the customer, is controlled by the control unit 44 and displays the input merchandize, the unit price, the total price and the like. The purchaser of the merchandize can recognize the input merchandize, the unit price, the total amount of the merchandize purchased and the like by the customer display 35.

The journal printer 37 is controlled by the control unit 44 and information about merchandise transacted on the day is printed as a transaction log one after another. Further, the receipt printer 38 is controlled by the control unit 44 and the merchandize, the unit price, the quantity, the total amount and the like are printed as a receipt and output for each transaction. The receipt printed by the receipt printer 38 is delivered to the customer.

The drawer 38 stores money. The control unit 44 controls opening of the drawer 38. The drawer 38 is opened by operating the keyboard 31 for receiving and paying money.

The external memory unit 46 is equipped with a replaceable memory device 47. For example, the program described above is installed by the external memory unit 46 from the replaceable memory device 47. Further, data processed by the control unit 44 based on the program described above is stored in the replaceable memory device 47 by the external memory unit 46.

A description will be given as to the transaction log managed by the server controller 11 and the POS terminal apparatus 12.

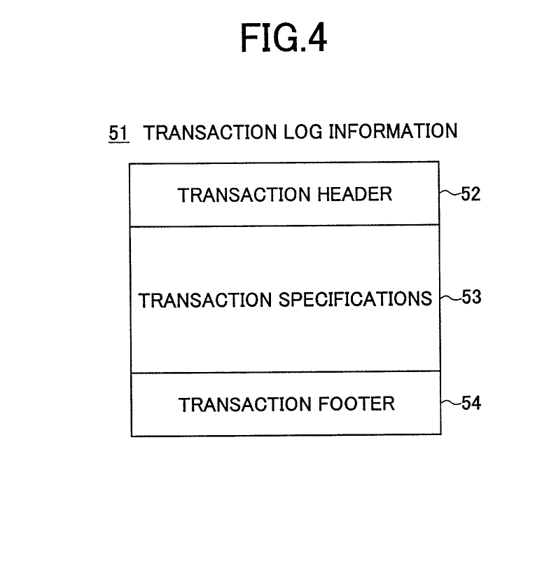

FIG. 4 shows a data structure of the transaction log information of the embodiment of the present invention.

The transaction log information 51 is a piece of information that is provided for each transaction, mainly including transaction header information 52, transaction specification information 53 and transaction footer information 54.

The transaction header information 52 will now be described in detail.

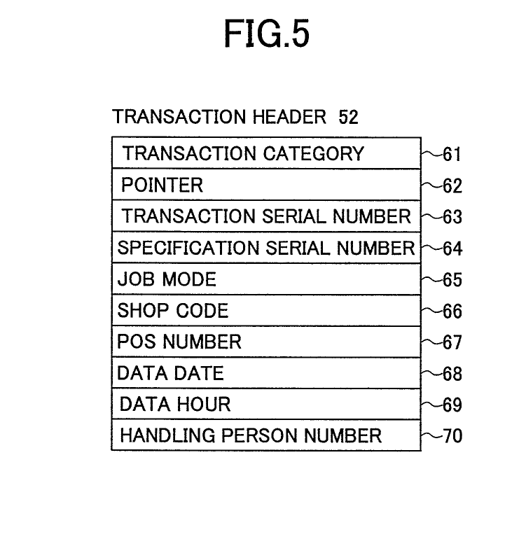

FIG. 5 shows a data structure of the transaction header information of the embodiment of the present invention.

The transaction header information 52 stores transaction category information 61, pointer information 62, transaction serial number information 63, specification serial number information 64, job mode information 65, a store code 66, POS number information 67, data date information 68, data time information 69, handling person number information 70 and the like.

The transaction category information 61 is information to identify types of transactions such as sales, work, payments and receipts, erroneous registrations, cash collections during business hours, abolishment, and the like. The pointer information 62 holds a pointer that distinguishes a status of a transaction.

The transaction serial number information 63 holds a transaction serial number for each transaction. The specification serial number information 64 holds a serial number of a specification.

The job mode information 65 holds information to distinguish a job mode, such as a normal transaction, a training operation or the like. The store code 66 holds a predetermined number indicative of a store where the transaction takes place. The POS number information 67 holds a number that is pre-assigned to the POS remote apparatus making the transaction among the POS terminal apparatuses 12 installed in the store.

The data date information 68 holds a date on which the transaction is conducted. The data time information 69 holds the time of the transaction conducted. The handling person number information 70 holds a pre-assigned number of a person who handles the transaction.

In the following, transaction specification information 53 will be described in detail.

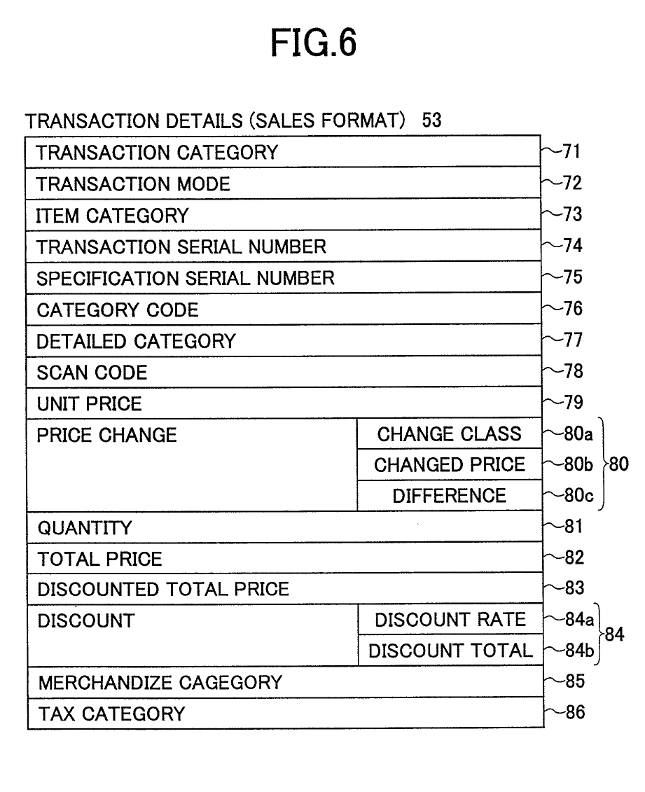

FIG. 6 shows a data structure of the transaction specification information of the embodiment of the present invention.

The transaction specification information 53 stores transaction category information 71, a transaction mode 72, item category information 73, transaction serial number information 74, specification serial number information 75, a category code 76, specification category information 77, a scan code 78, a unit price 79, price change information 80, a quantity 81, total price information 82, discounted total price information 83, discount information 84, a merchandize category 85, tax category information 86 and the like.

The transaction category information 71 holds information to distinguish types of transactions such as sales, work, payments and receipts, erroneous registrations, cash collections during business hours, abolishment, and the like, similar to the transaction category information 61 of the transaction header information 52. The transaction mode 72 holds a mode to identify the mode of the transaction such as normal, return, external sales and the like.

The item category information 73 holds information to distinguish a status of the transaction specification information that is to be generated, indicating whether it is for specifications, on-the-spot corrections, instructed corrections, or the like. The transaction serial number information 74 holds a transaction serial number. The specification serial number information 75 holds a serial number information of the specifications.

The category code 76 holds a merchandize category code. The specification category information 77 holds information to distinguish category of specifications as to whether it relates to merchandize, recovery of used containers, or the like. The scan code 78 holds a merchandise code read by the bar code reader 32. The unit price 79 holds a unit price of the merchandise.

The price change information 80 includes change category information 80a, changed price information 80b and price difference information 80c. In the change category information 80a, information is set to distinguish categories of changes as to whether there is no price change or, if there is a price change, whether it is a change by the head office, a change for a sales promotion, a change by an owner, or the like. In the changed price information 80b, revised price information is set. In the price difference information 80c, the price difference between normal and revised prices is set. In the quantity 81, the quantity of the sold merchandize is set. In the total price information 82, the total price amount is set. In the discounted total price information 83, the total discounted price is set when a discount or the like applies.

The discount information 84 includes discount rate information 84a and discounted total price 84b. In the discount rate information 84a, a discount rate is set. In the discounted total price 84b, a total amount of the discounted prices is set.

In the merchandize category 85, a category as to whether or not the merchandise is normal merchandise and the like are set. In the tax category information 86, an applicable tax category is set to indicate whether tax-exclusive, tax-inclusive or tax exempted or the like.

The transaction specification information 53 described above is set for each merchandise one after another.

In the following, a detailed description of the transaction footer 54 will be presented.

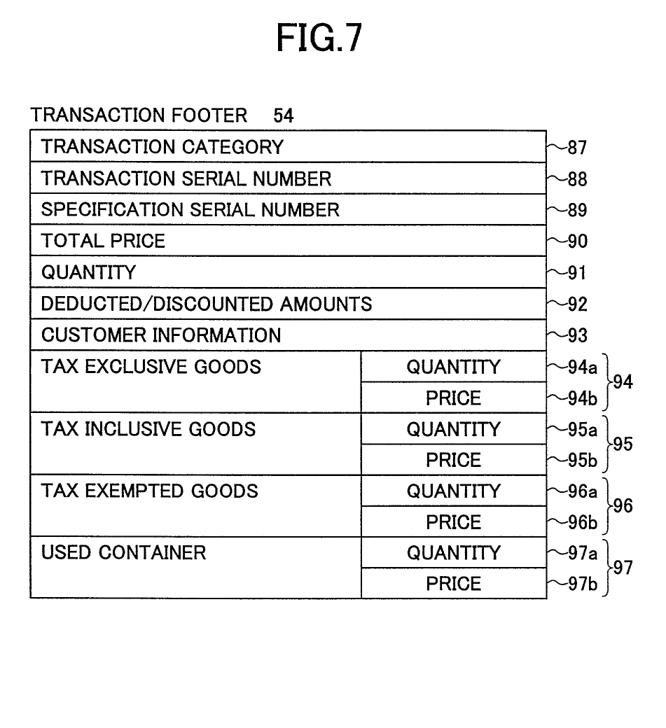

FIG. 7 shows a data structure of the transaction footer information of the embodiment of the present invention.

The transaction footer information 54 stores the transaction category information 87, the transaction serial number 88, the specification serial number 89, the total amount 90, the quantity information 91, the deducted amount/discounted amount information 92, the customer information 93, tax-exclusive merchandize total information 94, tax-inclusive merchandise total information 95, tax-exempted merchandize total information 96, used container information 97 and the like.

The transaction category information 87 holds information to distinguish categories of transactions such as sales, work, payments and receipts, erroneous registrations, cash collections during business hours, abolishment, and the like, similarly to the transaction category information 61 and 71 of the transaction header information 52 and the transaction specification information 53, respectively.

The transaction serial number 88 holds a transaction serial number similarly to the transaction serial numbers 63 and 74 for the transaction header information 52 and the transaction specification information 53, respectively. The specification serial number 89 holds a specification serial number similarly to the specification serial numbers 64 and 75 for the transaction header information 52 and the transaction specification information 53, respectively.

The total amount 90 holds a total price amount of the merchandise purchased. The quantity information 91 holds a quantity of the pieces of merchandise purchased.

The deducted amount/discounted amount information 92 holds information such as the discounted price/discounted amount of a whole of merchandize purchased. In the customer information 93, customer information such as an age group and the like are set. The customer information 93 is input by the cashier operating the keyboard according to his/her intuition upon seeing the purchaser.

The tax-exclusive merchandise total information 94 includes quantity information 94a and price amount information 94b. The quantity information 94a holds a quantity of tax-exclusive merchandise pieces. The price amount information 94b holds a price amount of the tax-exclusive merchandise.

The tax-inclusive merchandize total information 95 includes quantity information 95a and price amount information 95b. The quantity information 95a holds a quantity of tax-inclusive merchandize pieces. The price amount information 95b holds a price amount of the tax-inclusive merchandise.

The tax-exempted merchandize total information 96 includes quantity information 96a and price amount information 96b. The quantity information 96a holds a quantity of tax-exempted merchandize pieces. The price amount information 96b holds a price amount of the tax-exempted merchandise.

The used container information 97 stores information relative to used container recoveries. The used container information 97 includes quantity information 97a and price amount information 97b. The quantity information 97a holds a quantity of used containers. The price amount information 97b holds a price amount of used containers.

In above, the structure of the transaction log information 51 has been described. The transaction log information 51 described above is generated by the POS terminal apparatus 12 for each transaction and is memorized by the memory unit 45 of the POS terminal apparatus 12 in the order of transactions sequentially. Then, the transaction log information 51 of each POS terminal apparatus 12 is settled every 24 hours so that the previous day portion and the present day portion are managed separately.

In the server controller 11 and in the POS terminal apparatuses 12, hard total information summarizing transactions handled by each of the POS terminal apparatuses 12 in 24 hours is generated by the settlement process.

Here, a detailed description of the hard total information will be given.

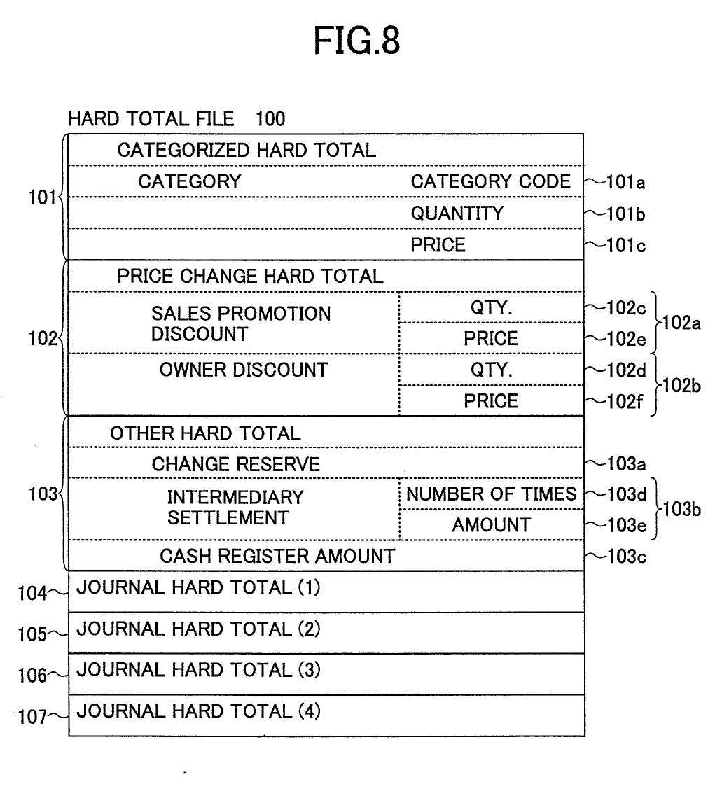

FIG. 8 shows a data structure of the hard total information of the embodiment of the present invention.

The hard total information 100 stores categorized hard total information 101, discounted/raised price hard total information 102, other hard total information 103, a plurality of journal hard total information pieces 104 through 107 and the like.

The categorized hard total information 101 is hard total information for each merchandize category code and holds quantity information 101b corresponding to each of category code information 101a and the total price information 101c.

The discounted/raised price hard total information 102 is information relative to the hard total resulting from the discounted or raised price, and includes, for example, information relative to discounts for sales promotion 102a and information relative to discounts by the store owner 102b. Each piece of the information 102a and 102b provides corresponding item's quantity information 102c and 102d, respectively, and the total price amount information 102e and 102f, respectively.

The other hard total information 103 provides, for example, change reserve information 103a, intermediary cash collection information 103b, and a cash register registration amount 103c. The change reserve information 103a holds a change reserve amount that is deposited to the drawer 38 of the POS terminal apparatus 12 in advance. Further, the intermediary cash collection information 103b includes number-of-times information 103d and amount information 103e. The number-of-times information 103d holds a number of the intermediary cash collections and the amount information 103e holds a total amount of the cash collected. Further, the cash register registration amount information 103c holds a total amount registered by the cash register.

In the following, a description of journal hard total information pieces 104 through 107 will be given.

First, the journal hard total information 104 will be described. The journal hard total information 104 registers a journal of the hard total of sales at the cash register.

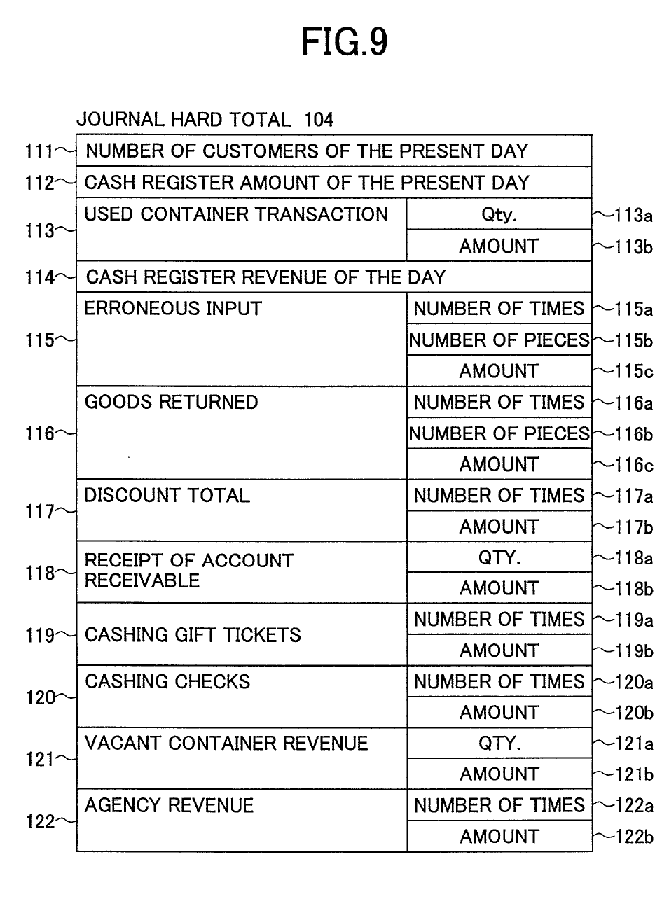

FIG. 9 shows a data structure of the journal hard total information of the embodiment of the present invention. The journal hard total information 104 stores present day customer number information 111, present day cash register registration amount information 112, used container transaction information 113, present day cash register revenue amount information 114, erroneous registration information 115, returned goods information 116, reduced price/discount information 117, account receivable recovery information 118, gift ticket cashing information 119, check cashing information 120, used container revenue information 121, agent revenue information 122 and the like.

In the present day customer number information 111, the total number of customers on the present day is set. In the present day cash register registration amount information 112, the total amount registered at the cash register on the present day is set.

In the used container transaction information 113, the information relative to the total of the used container transactions is set. The used container transaction information 113 includes quantity information 113a and price amount information 113b. The quantity information 113a holds the number of used containers transacted. The price amount information 113b holds the total price amount of the used containers transacted.

In the present day cash register revenue amount information 114, the total cash register revenue of the present day is set. The erroneous registration information 115 includes number-of-times information 115a, quantity information 115b and price amount information 115c. In the number-of-times information 115a, the quantity information 115b and the price amount information 115c, the number of erroneous registrations, the number of pieces of merchandise erroneously registered and the total price amount of the erroneous registrations are set, respectively.

The returned goods information 116 includes number-of-times information 116a, quantity information 116b and price amount information 116c. In the number-of-times information 116a, the quantity information 116b and the price amount information 116c, the number of times of the goods return, the number of pieces of the returned goods and the total price amount of the returned goods are set, respectively.

The reduced price/discount information 117 includes number-of-times information 117a and price amount information 117b. In the number-of-times information 117a, the number of price reductions/discounting events is set. In the price amount information 117b, the total amount of the reduced prices/discounts is set.

The account receivable recovery information 118 includes number-of-times information 118a and price amount information 118b. The number-of-times information 118a holds the number of times of account receivable recoveries of the present day. The price amount information 118b holds the total account receivable recovery amount of the present day.

Gift ticket cashing information 119 includes number-of-times information 119a and amount information 119b. The number-of-times information 119a holds the number of times of gift ticket cashing cases. The amount information 119b holds the total monetary amount of the gift tickets cashed.

Check cashing information 120 includes number-of-times information 120a and amount information 120b. The number-of-times information 120a holds the number of times of check cashing cases. The amount information 120b holds the monetary amount of the checks cashed.

The used container revenue information 121 includes number-of-times information 121a and amount information 121b. The number-of-times information 121a holds the number of times of revenues from used containers. The amount information 121b holds the total monetary amount of revenues from the used containers.

The agent revenue information 122 includes number-of-times information 122a and amount information 122b. The number-of-times information 122a holds the number of times of revenues for the agency. The amount information 122b holds the total amount of the agency revenues.

In the following, the journal hard total information 105 will be described.

In the journal hard total information 105, a total of non-operating revenues and the like is set.

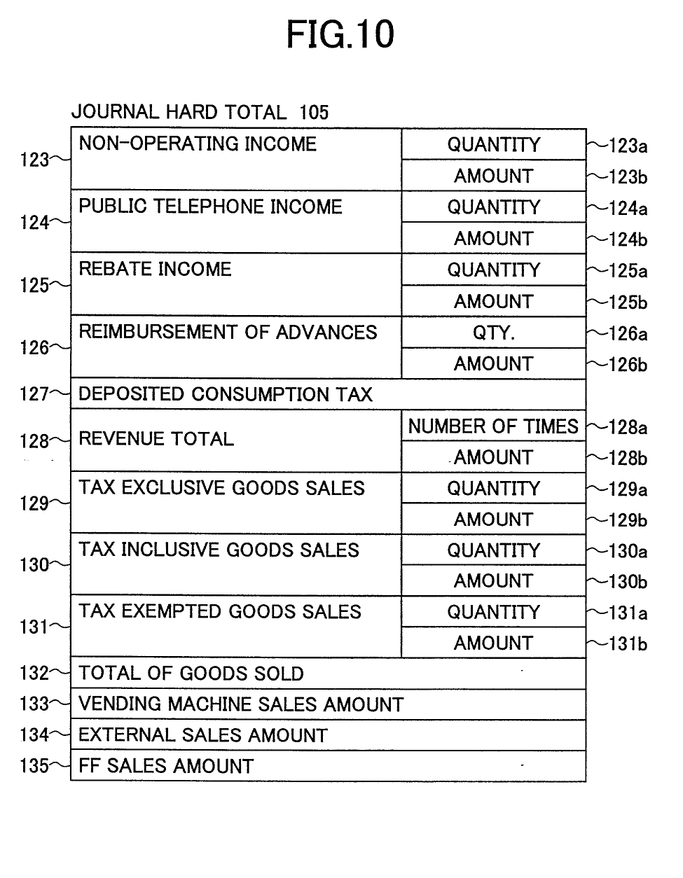

FIG. 10 shows a data structure of the journal hard total information of the embodiment of the present invention.

The journal hard total information 105 stores non-operating revenue information 123, public telephone revenue information 124, rebate revenue information 125, advanced money reimbursement information 126, deposited consumption tax information 127, received fund total information 128, tax-exclusive merchandize sales information 129, tax-inclusive merchandise sales information 130, tax-exempted merchandize sales information 131, merchandise sales amount information 132, automatic vending machine sales amount information 133, external sales information 134, FF sales information 135 and the like.

The non-operating revenue information 123 includes number-of-times information 123a and amount information 123b. The number-of-times information 123a holds the number of non-operating revenues and in the amount information 123b, the total monetary amount of the non-operating revenues is set.

The public telephone revenue information 124 includes number-of-times information 124a and amount information 124b. The number-of-times information 124a holds the number of times of the public telephone revenues. The amount information 124b holds the total amount of the public telephone revenues.

The rebate revenue information 125 includes number-of-times information 125a and amount information 125b. The number-of-times information 125a holds the number of rebate revenues. The amount information 125b holds the total amount of the rebate revenues.

The advanced money reimbursement information 126 includes number-of-times information 126a and amount information 126b. In the number-of-times information 126a, the number of advanced money reimbursements is set. In the amount information 126b, the total amount of advanced money reimbursements is set.

In the deposited consumption tax information 127, the total amount of the consumption tax deposited is set.

The received fund total information 128 includes number-of-times information 128a and amount information 128b. In the number-of-times information 128a, the number of fund receipts is set. In the amount information 128b, the total amount of the received funds is set.

The tax-exclusive sales information 129 includes quantity information 129a and price amount information 129b. In the quantity information 129a, the number of pieces of tax-exclusive merchandize is set. In the price amount information 129b, the total sales amount of the tax-exclusive merchandise sold is set.

The tax-inclusive sales information 130 includes quantity information 130a and price amount information 130b. In the quantity information 130a, the number of pieces of tax-inclusive merchandise sold is set. In the price amount information 130b, the total sales amount of the tax-inclusive merchandise is set.

The tax-exempted sales information 131 includes quantity information 131a and price amount information 131b. In the quantity information 131a, the number of pieces of tax-exempted merchandise is set. In the price amount information 131b, the total sales amount of the tax-exempted merchandise sold is set.

In the merchandise sales amount information 132, the total sales amount of the present day is set. In the automatic vending machine sales amount information 133, the total sales amount of merchandize sold by the automatic vending machines installed in the store on the present day is set. In the FF sales information 135, the total amount of FF sales is set.

In the following, the journal hard total information 106 will be described.

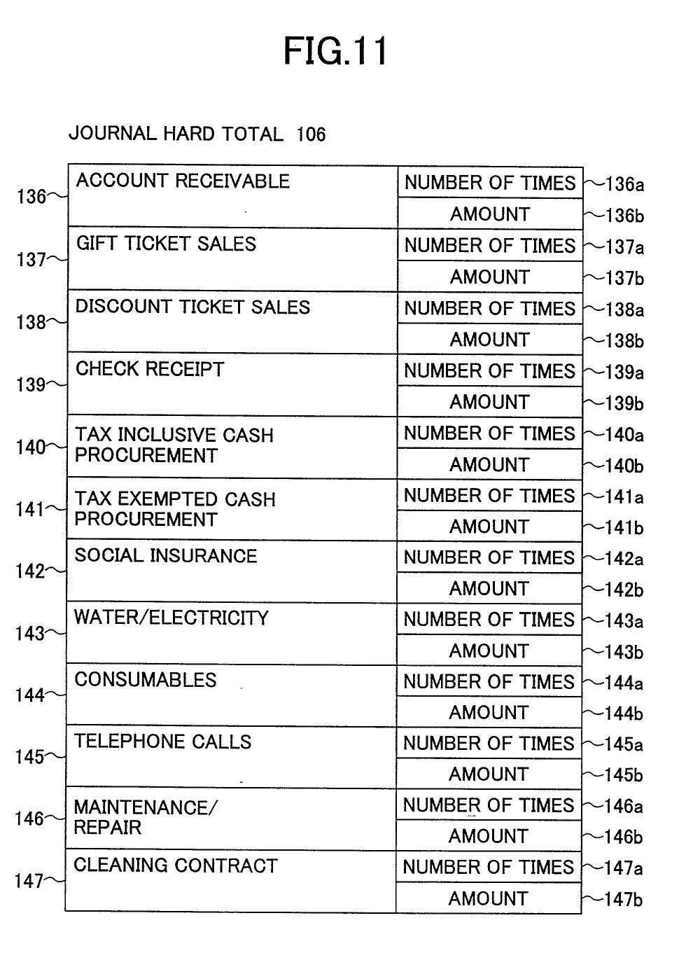

FIG. 11 shows a data structure of the journal hard total information of the embodiment of the present invention.

The journal hard total information 106 stores account receivable information 136, gift ticket sales information 137, discount ticket sales information 138, check receipt information 139, tax-inclusive cash procurement information 140, tax-exempted cash procurement information 141, social security fee information 142, water/lighting-heating expense information 143, consumables expense information 144, telephone charge information 145, maintenance and repair expense information 146, cleaning expense information 147 and the like.

The account receivable information 136 includes number-of-times information 136a and amount information 136b. In the number-of-times information 136a, the number of account receivables of the present day is set. In the amount information 136b, the total account receivable amount of the present day is set.

The gift ticket sales information 137 includes number-of-times information 137a and amount information 137b. In the number-of-times information 137a, the number of transactions by a gift ticket of the present day is set. In the amount information 137b, the total amount of the transactions by the gift ticket of the present day is set.

The discount ticket sales information 138 includes number-of-times information 138a and amount information 138b. In the number-of-times information 138a, the number of transactions by a discount ticket of the present day is set. In the amount information 138b, the total amount of the transactions by discount tickets of the present day is set.

The check receipt information 139 includes number-of-times information 139a and amount information 139b. In the number-of-times information 139a, the number of check receipts of the present day is set. In the amount information 139b, the total amount of the check receipts of the present day is set.

The tax-inclusive cash procurement information 140 includes number-of-times information 140a and amount information 140b. In the number-of-times information 140a, the number of tax-inclusive cash procurements of the present day is set. In the amount information 140b, the total amount of the tax-inclusive cash procurements of the present day is set.

The tax-exempted procurement information 141 includes number-of-times information 141a and amount information 141b. In the number-of-times information 141a, the number of tax-exempted procurements of the present day is set. In the amount information 141b, the total amount of the tax-exempted procurements of the present day is set.

The social security fee information 142 includes number-of-times information 142a and amount information 142b. In the number-of-times information 142a, the number of social security payments of the present day is set. In the amount information 142b, the total amount of social security payments of the present day is set.

The water/lighting-heating expense information 143 includes number-of-times information 143a and amount information 143b. In the number-of-times information 143a, the number of water/lighting-heating expense payments of the present day is set. In the amount information 143b, the total amount of water/lighting-heating expense payments of the present day is set.

The consumables expense information 144 includes number-of-times information 144a and price amount information 144b. In the number-of-times information 144a, the number of consumables expense payments of the present day is set. In the amount information 144b, the total amount of consumables expense payments of the present day is set.

The telephone charge information 145 includes number-of-times information 145a and amount information 145b. In the number-of-times information 145a, the number of telephone charge payments of the present day is set. In the amount information 145b, the total amount of telephone charge payments of the present day is set.

The maintenance and repair charge information 146 includes number-of-times information 146a and amount information 146b. In the number-of-times information 146a, the number of maintenance and repair payments of the present day is set. In the amount information 146b, the total amount of maintenance and repair payments of the present day is set.

The cleaning expense information 147 includes number-of-times information 147a and amount information 147b. In the number-of-times information 147a, the number of cleaning expense payments of the present day is set. In the amount information 147b, the total amount of cleaning expense payments of the present day is set.

In the following, the journal hard total information 106 will be described in detail.

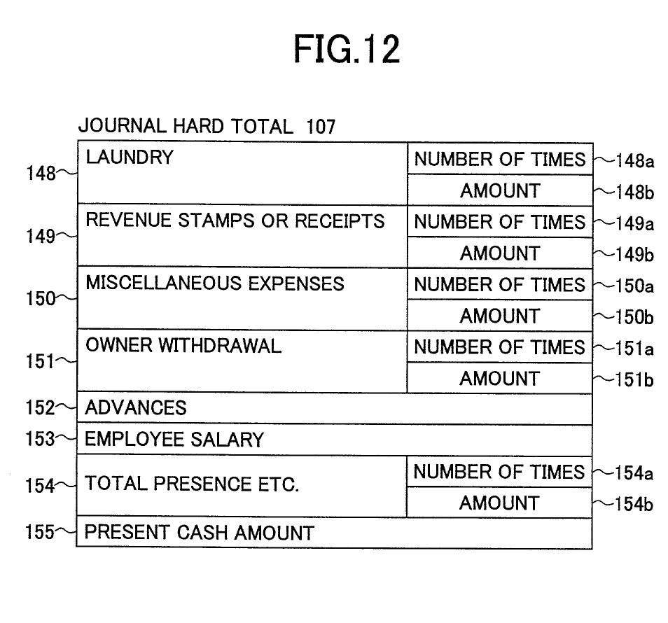

FIG. 12 shows a data structure of the journal hard total information of the embodiment of the present invention.

The journal hard total information 107 includes laundry expense information 148, receipts' revenue stamp information 149, miscellaneous expense information 150, owner withdrawal information 151, advanced money information 152, employee salary information 153, payments and others total information 154 and current balance information 155.

The laundry expense information 148 includes number-of-times information 148a and amount information 148b. In the number-of-times information 148a, the number of payments for laundries on the present day is set. In the amount information 148b, the total amount of the laundry expense payments on the day is set.

The receipts' revenue stamp information 149 includes number-of-times information 149a and amount information 149b. In the number-of-times information 149a, the number of payments for revenue stamps for receipts on the present day is set. In the amount information 149b, the total payment amount of the revenue stamps for receipts on the day is set.

The miscellaneous expenses information 150 includes number-of-times information 150a and amount information 150b. In the number-of-times information 150a, the number of payments for miscellaneous expenses on the present day is set. In the amount information 150b, the total amount of the miscellaneous expense payments on the day is set.

The owner withdrawal information 151 includes number-of-times information 151a and amount information 151b. In the number-of-times information 151a, the number of cash withdrawals by the owner on the present day is set. In the amount information 151b, the total amount of the owner withdrawals on the day is set.

In the advanced money information 152, the total of the advanced money of the present day is set. In the employee salary information 153, the total amount of salaries paid to employees on the day is set.

The payments and others total information 154 includes number-of-times information 154a and amount information 154b. In the number-of-times information 154a, the number of payments and the like of the present day is set. In the amount information 154b, the total amount of the payments and the like on the day is set. In the current balance information 155, an amount of cash in presence on the present day is set.

Further, the server controller 11 holds POS settlement management information. The server controller 11 performs a settlement process based on the transaction log information of the POS terminal apparatus 12 according to the given POS settlement management information.

Here, a description of the POS settlement management information will be given.

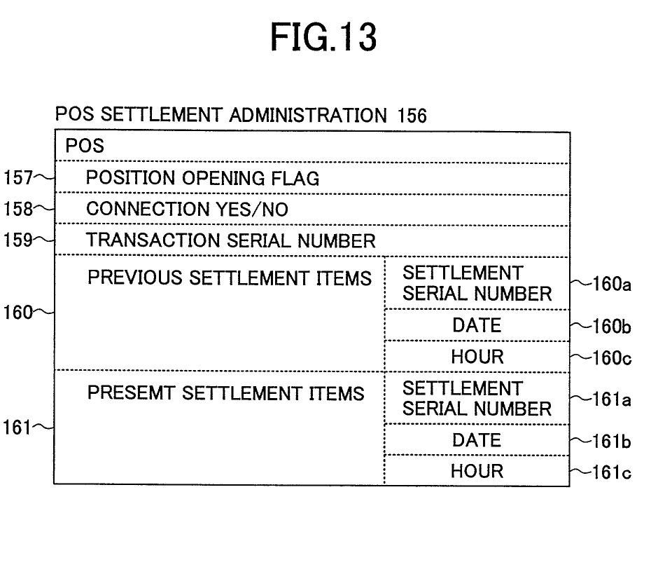

FIG. 13 shows a data structure of the POS settlement management information of the embodiment of the present invention.

As regards the POS settlement management information 156, it is provided in each of the POS terminal apparatuses 12, and stores a position opening flag 157, a presence-or-absence-of-the-connection flag 158, transaction serial number information 159, last settlement item information 160, current settlement item information 161 and the like.

In the position opening flag 157, a flag is provided for checking whether or not the corresponding POS terminal apparatus 12 is open. The presence-or-absence-of-the-connection flag 158 holds a status of presence or absence of the connection to the corresponding POS terminal apparatus 12.

In the transaction serial number information 159, the transaction serial number of the last settlement for the corresponding POS terminal apparatus 12 is set. The last settlement item information 160 includes settlement serial number information 160a, date information 160b, and time information 160c for storing the settlement serial number, date and time, respectively, for the last settlement. The current settlement item information 161 includes settlement serial number information 161a, date information 161b, and time information 161c for storing the serial number, date and time, respectively, for the current settlement.

The server controller 11 performs the settlement process by accessing the POS terminal 12 according to the POS settlement management information 156 described above.

Further, the POS terminal apparatus 12 is provided with transaction log pointer management information, and the POS terminal apparatus 12 manages the transaction log based on the given transaction log pointer management information.

Here, the transaction log pointer management information will be described in detail.

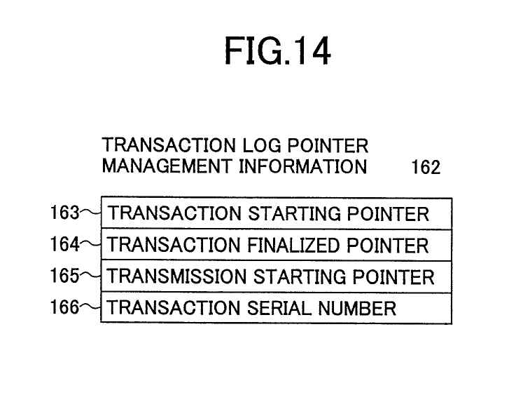

FIG. 14 shows a data structure of the transaction log pointer management information of the embodiment of the present invention.

The transaction log pointer management information 162 stores transaction starting pointer information 163, transaction finalized pointer information 164, transmission starting pointer information 165, transaction serial number information 166 and the like.

The next transaction starting position in the transaction log designates the transaction starting pointer information 163. The transaction finalized pointer information 164 designates the position where a transaction is finalized in the transaction log. The transmission starting pointer information 165 designates the next position in the transaction log to be transmitted to the server controller 11. In the transaction serial number information 166, the transaction serial number is set.

In the following, operations of the POS terminal apparatus 12 of the embodiment of the present invention during the normal process will be described.

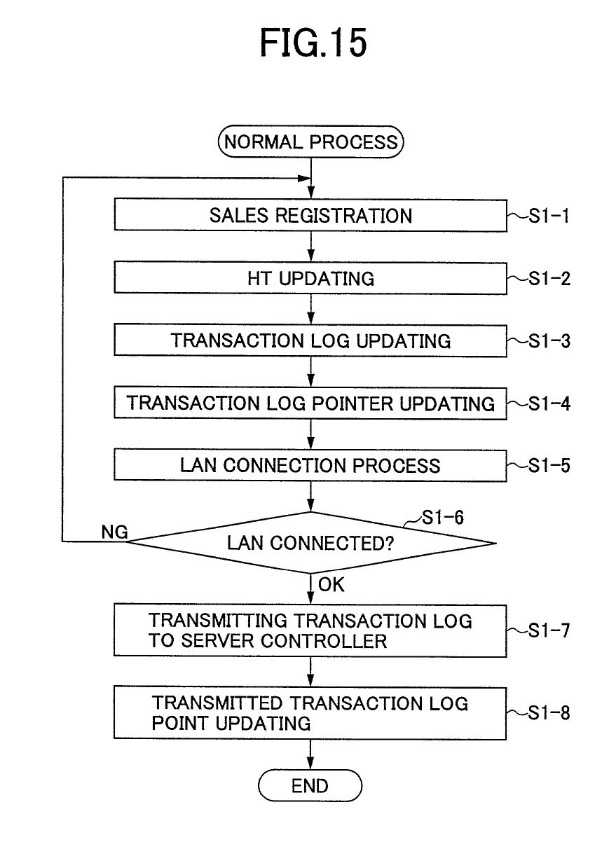

FIG. 15 is a process flowchart of the POS terminal apparatus during the normal process of the embodiment of the present invention.

In the POS terminal apparatus 12, when a registration of sales and the like is made by operating the keyboard 31 and the bar code reader 32 (step S1-1), the above mentioned hard total information 100 provided in the POS terminal apparatus 12 is updated based on input information such as registered bard codes, customer information and the like input by key operations (step S1-2). Further, the transaction log information 51 is updated similarly (step S1-3). And then, the transaction log pointer management information 162 described above is updated based on the updated results through the steps S1-2 and S1-3 (step S1-4).

Subsequently, the POS terminal apparatus 12 is connected to the server controller 11 via the LAN circuit 13 (step S1-5). When the POS terminal apparatus 12 is connected to the server controller 11 via the LAN circuit 13 (step S1-6), the transaction log information 51 that is added to by the step S1-3 is transmitted to the server controller 11 (step S1-7).

When the transaction log information 51 is transmitted by the step S1-7, the transmission starting pointer information of the transaction log pointer management information 162 described above is updated (step S1-8).

At this time, if the connection of the server controller is not confirmed for any reason in the LAN circuit, the transaction log pointer management information 165 is not updated, and the process returns to the step S1-1.

Above is the process of the POS terminal apparatus 12 during the normal process.

In the following, the process of the server controller 11 during the normal process will be described.

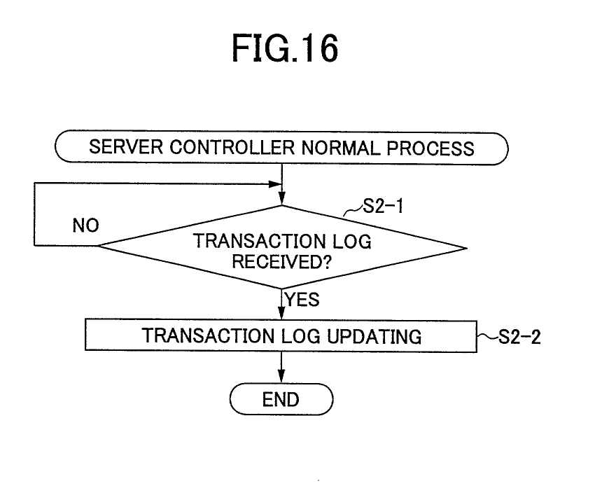

FIG. 16 is a process flowchart of the server controller during the normal process of the embodiment of the present invention.

When the server controller 11 receives the transaction log information 51 from the POS terminal apparatus 12 via the LAN circuit 13, it updates the transaction log information 51 of the present day stored in the server controller 11, and finishes the process (step S2-2).

In the following, the process in the POS terminal apparatus 12 during the settlement process will be described.

The settlement process takes places, for example, at a predetermined interval of every 24 hours.

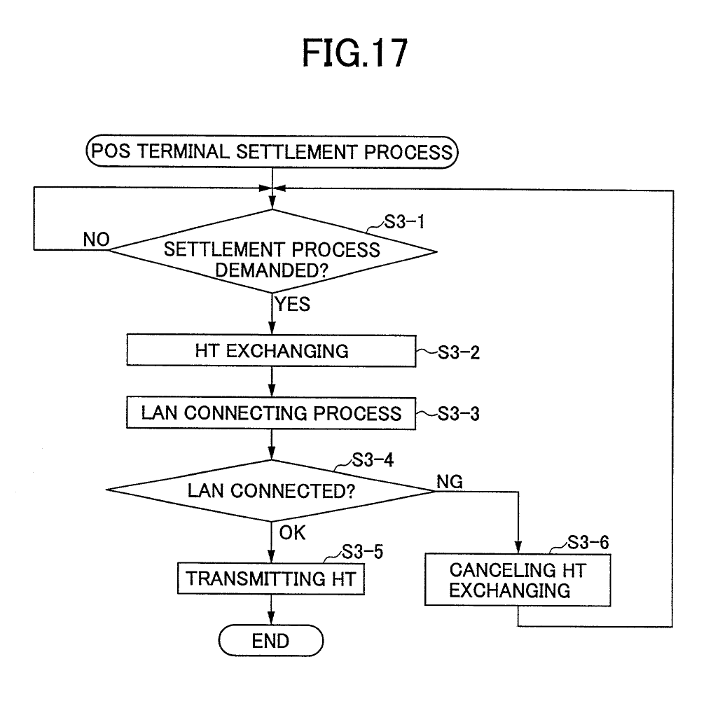

FIG. 17 is a process flowchart of the POS terminal apparatus for the settlement process of the embodiment of the present invention.

When the POS terminal apparatus 12 performs the settlement process, it issues a settlement process demand. When the settlement process demand is issued, the area for the hard total information for the previous day 100 is made the area for the hard total information 100 of the present day, and the area for the hard total information 100 of the present day is switched to the area of the hard total information 100 for the previous day (step S3-2).

Then, a connection is made to the server controller 11 via the LAN circuit 13 (step S3-3).

When the connection is made to the server controller 11 through the step S3-3 (step S3-4), the hard total information 100 that is set to the hard total information 100 of the previous day by the step S3-2 is transmitted to the server controller 11, and the process finishes (step S3-5). If the connection was not made to the server controller 11 in the step S3-4, the area switching between the previous day portion and the present day portion in the step S3-2 is cancelled, to stand-by for a next settlement demand (step S3-6).

In the following, the process of the server controller 11 at the settlement process will be described.

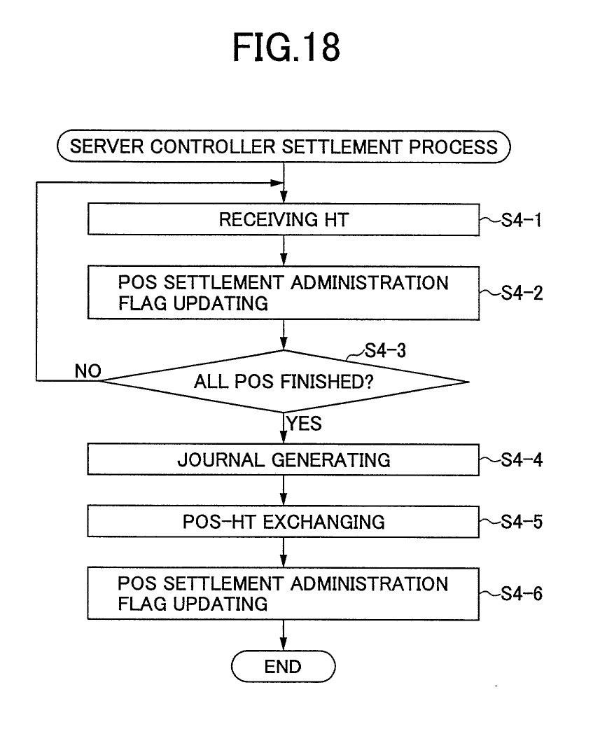

FIG. 18 is a process flowchart of the server controller for the settlement process of the embodiment of the present invention.

When the server controller 11 receives the hard total information 100 from the POS terminal apparatus 12 (step S4-1), it first updates the POS settlement management information 156 (step S4-2) described in FIG. 13.

While the hard total information 100 is being received from the POS terminal apparatus 12 in the step S4-1, the POS settlement management information 156 is updated in the step S4-2 and a checking is made as to whether the hard total information 100 is received from all of the POS terminals connected to the LAN circuit 13 based on the POS settlement management information 156 (step S4-3). If the hard total information 100 has not been received from all of the POS terminals connected to the LAN circuit 13 in the step S4-3, the processes in the steps S4-1 through S4-3 described above are repeated so that the hard total information 100 for all of the POS terminals connected to the LAN circuit 13 is received.

When the hard total information 100 for all of the POS terminals connected to the LAN circuit 13 is received in the step S4-3, the server controller 11 adds up the acquired hard total information 100 of the POS terminal apparatuses 12 to generate hard total information for each store, which has a similar structure to FIG. 8 (step S4-4).

When the hard total information for each of the stores is generated in the step S4-4, the server controller 11 exchanges the transaction log information area for the previous day and the transaction log information area of the present day (step S4-5). When the exchange of the previous day transaction log information area and the present day transaction log information area is finished by the step S4-5, POS settlement management flag is updated (step S4-6).

In the following, a process of the server controller 11 in the recovery process will be described. The recovery process is performed by an instruction of an operator at the replacement of a hard drive or the like due to faults and the like of the POS terminal apparatus 12.

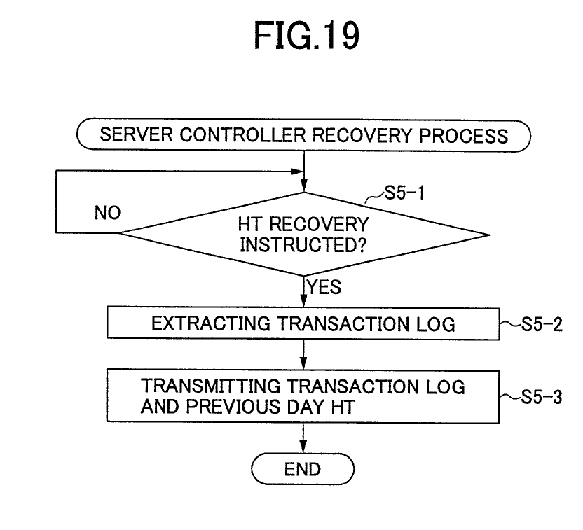

FIG. 19 is a process flowchart of the server controller for the recovery process of the embodiment of the present invention.

When the server controller 11 receives an instruction for the recovery from the POS terminal apparatus 12 (step S5-1), it searches and extracts the present day transaction log information and the stored previous day hard total information of the POS terminal apparatus 12 in which the hard drive has been replaced based on a pre-assigned terminal number (step S5-2).

The present day transaction log information and the previous day hard total information extracted in the step S5-2 are transmitted to the corresponding POS terminal apparatus 12 via the LAN circuit 13 (step S5-3).

In the following, a process of the POS terminal apparatus 12 in the recovery process will be described.

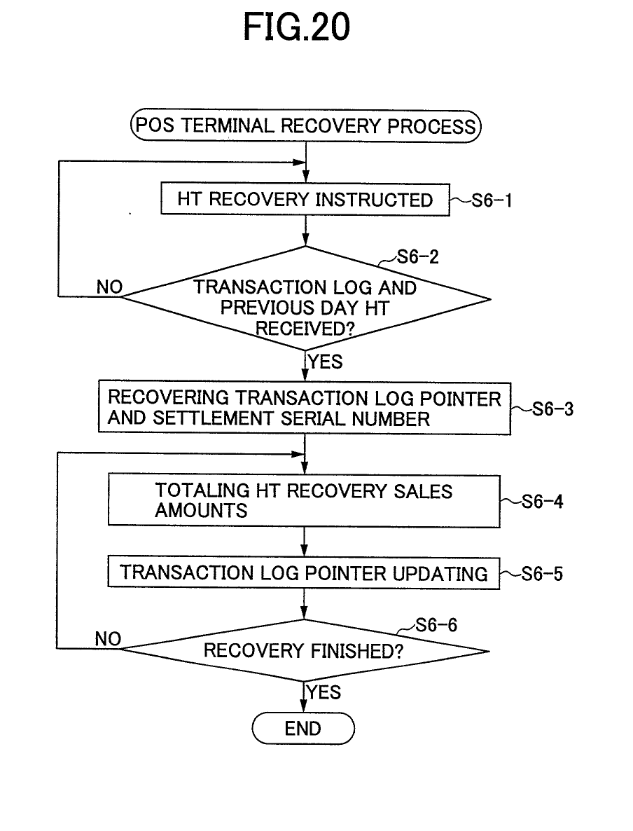

FIG. 20 is a process flowchart of the POS terminal apparatus for the recovery process of the embodiment of the present invention.

When the instruction is issued by the operator for the recovery process, the hard total recovery process instruction is transmitted to the server controller 11 (step S6-1). The hard total recovery process instruction includes transmission of an apparatus number of the POS terminal apparatus 12 and the like.

As the result of the instruction of the recovery process from the POS terminal apparatus 12 to the server controller 11 in the step S6-1, the present day transaction log information and the previous day hard total information are received from the server controller 11 (step S6-2). Then, the previous day hard total information and the present day transaction log information are recovered and the transaction log pointer management information 162 is restored to a state immediately before the corresponding day portion, that is, immediately before the settlement process, based on the previous day hard total information (step S6-3).

The recovery is performed by storing the previous day hard total information 100′ and the present day transaction log information 51 transmitted from the server controller 11 in the replaced hard drive of the POS terminal apparatus 12, thereby recovering the previous day hard total information 100′ and the present day transaction log information 51. In this manner, the settlement serial number 160a that is stored in the previous day hard total information 100′ is recovered.

Subsequently, in the step S6-3, each transaction in the present day transaction log information 51 is sequentially added up to recover the present day hard total information 100 (step S6-4).

Further, when the present day transaction log information 51 is added up for each transaction in the step S6-4, the settlement serial number of the present day transaction log information 51 is updated and the settlement serial number (transaction serial number) of the transaction log pointer management information 162 is recovered by incrementing the settlement serial number 160a of the previous day hard total information 100′, which is recovered by the step S6-3 when each transaction in the transaction log information 51 is sequentially added up (step S6-5). The steps S6-4 and S6-5 described above are repeated for each transaction in the present day transaction log information 51 that is recovered by the step S6-3 until there is no present day transaction log information 51 (step S6-6).

As above, the POS terminal apparatus 12 is put back to where it was immediately before the fault. If the hard drive is replaced or other repairs take place due to the fault in the POS terminal apparatus 12, the present day transaction log information and the hard total information stored in the POS terminal 12 can be recovered.

In the following, operations during the normal process will be described with reference to drawings.

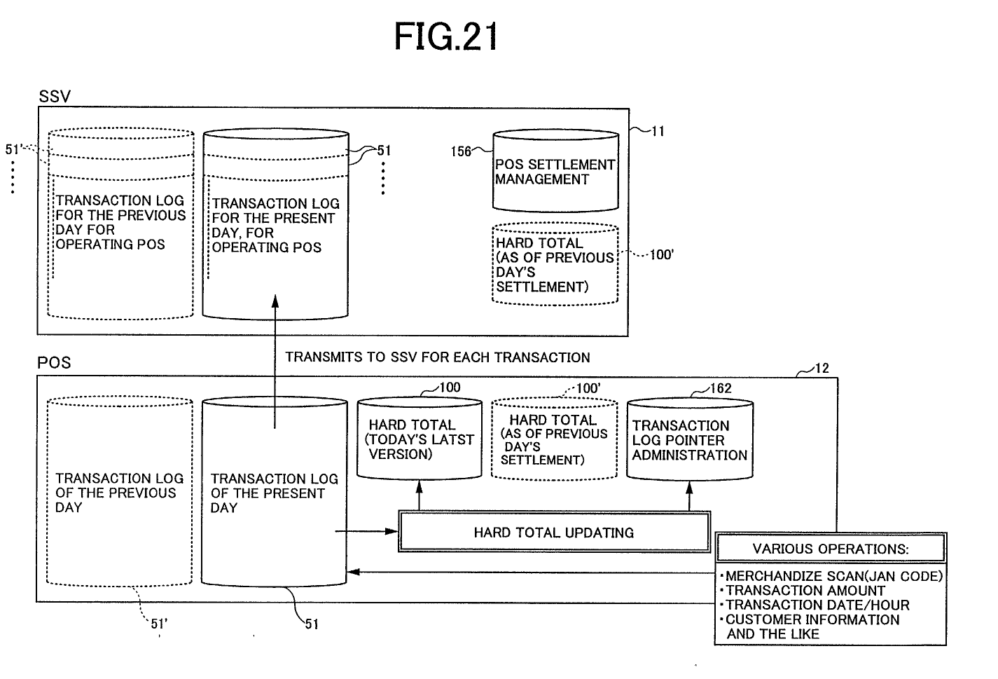

FIG. 21 describes operations during the normal process of the embodiment of the present invention.

In the normal process, the POS terminal apparatus 12 generates the transaction log information 51 for each transaction as shown in FIGS. 4 through 7 when a transaction takes place at the POS terminal apparatus 12, and stores it in the memory unit 45 of the POS terminal apparatus 12 as the present day transaction log information 51. Further, the POS terminal apparatus 12 updates the present day hard total information 100 as shown in FIGS. 8 through 14, based on the present day transaction log information 51 managed by the memory unit 45.

Further, the transition log information 51 is transmitted from the POS terminal apparatus 12 to the server controller 11 and stored in a present day operating apparatus transaction log information management area 27a of the memory unit 27 of the server controller 11. For this purpose, the transaction log information 51 is managed by the POS terminal apparatus 12 and the server controller 11 synchronously. That is, the transaction log information 51 in the POS terminal apparatus 12 and the server controller 11 hold the same information. If a plurality of POS terminal apparatuses 12 are connected to the server controller 11, it manages the transaction log information 51 of the plurality of the POS terminal apparatuses 12 in a mixed manner.

Further, in the POS terminal apparatus 12, the previous day transaction log information 51′ and the previous day hard total information 100′ are managed by the memory unit 45 in addition to the present day transaction log information 51 and the present day hard total information. Further, because the present day transaction log information is sequentially added up for each transaction sequentially and the present day hard total information 100 is sequentially updated according to the added transaction log information in the POS terminal apparatus 12, the transaction log pointer management information 162 is controlled by the memory unit 45 as shown in FIG. 14 to manage the status of the present day transaction log information 51.

Further, in the settlement process, the server controller 11 handles the present day transaction log information 51 that has been stored by then as the previous day portion and handles the hard total information obtained from the POS terminal apparatus 12 as the present day portion.

At this time, the server controller 11 controls the POS settlement management information 156 as shown in FIG. 13 to manage the POS terminal apparatus 12 for which the settlement process has been performed. When the settlement process takes place, the server controller 11 updates the POS settlement management information 156 corresponding to the POS terminal apparatus 12 for which the settlement process has been performed.

In the following, operations during the settlement process of the present embodiment will be described.

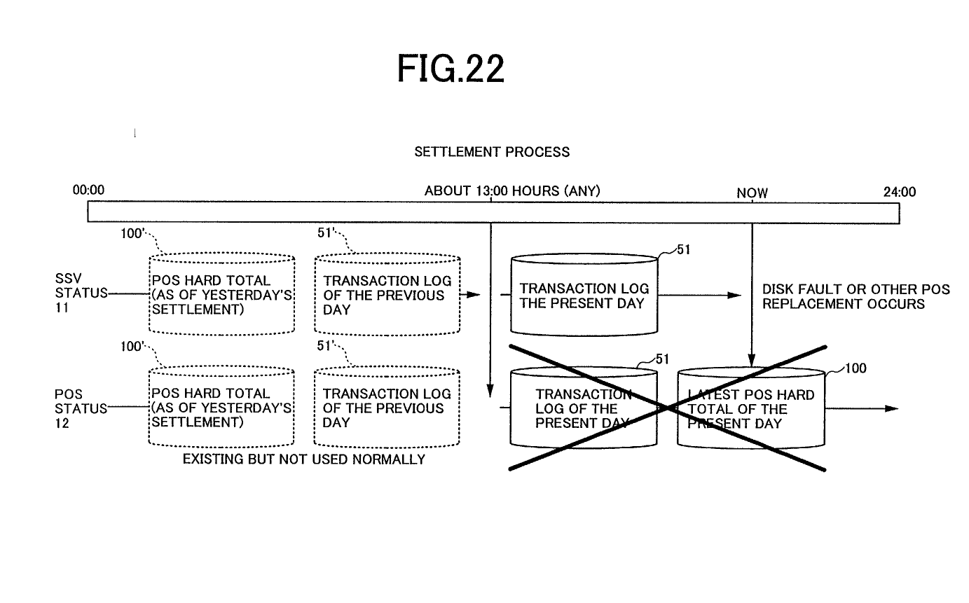

FIG. 22 describes the operations during the settlement process of the embodiment of the present invention.

The settlement process is performed at an arbitrarily predetermined time. For example, as shown in FIG. 22, at 13:00 hours, the server controller 11 saves the transaction log information stored for transactions between 13:00 hours of the previous day and 13:00 hours of the present day as the previous day transaction log information. At this instant, the server controller 11 receives and saves the hard total information that is updated by the POS terminal apparatus 12 based on the transaction log information for transactions at the POS terminal apparatus between 13:00 hours of the previous day and 13:00 hours of the present day as the previous day hard total information. Further, for transactions after 13:00 hours of the present day, the transaction log information received from the POS terminal apparatus 12 is stored as the present day transaction log information.

Further, at the 13:00 hours, as shown in FIG. 22, the POS terminal apparatus 12 saves the transaction log information stored between 13:00 hours of the previous day and 13:00 hours of the present day as the previous day transaction log information. Further, the log information of transactions after 13:00 hours of the present day is stored as the present day transaction log information 51. Further, the POS terminal apparatus 12 sequentially updates the hard total information 100 based on the transaction log information 51 that is generated by transactions after 13:00 hours, and generate and stores the present day hard total information 100.

In FIG. 22, a fault is assumed to occur in the POS terminal apparatus 12 at the present time t after 13:00 hours, thereby destroying the transaction log information and the hard total information of the previous day and the present day. When the hard drive in the POS terminal apparatus 12 where the fault occurs is replaced, the transaction log information 51 and 51′, and the hard total information 100 and 100′ for the previous day and the present day, respectively, have been lost in the POS terminal apparatus 12. Accordingly, if transactions are continued, the transaction log information 51 and the hard total information 100 stored in the server controller 11 will not match with the transaction log information 51 and the hard total information 100 stored in the POS terminal apparatus 12. When this situation arises, the recovery process is performed.

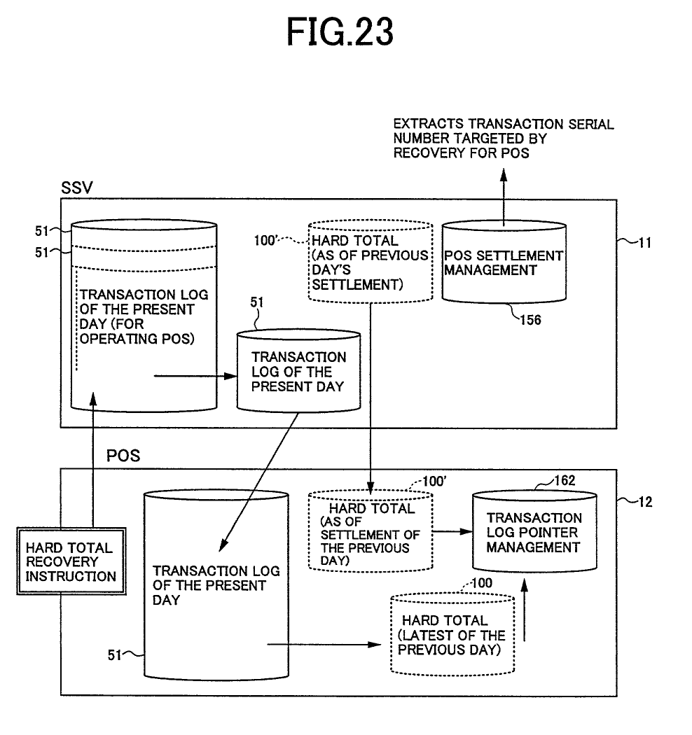

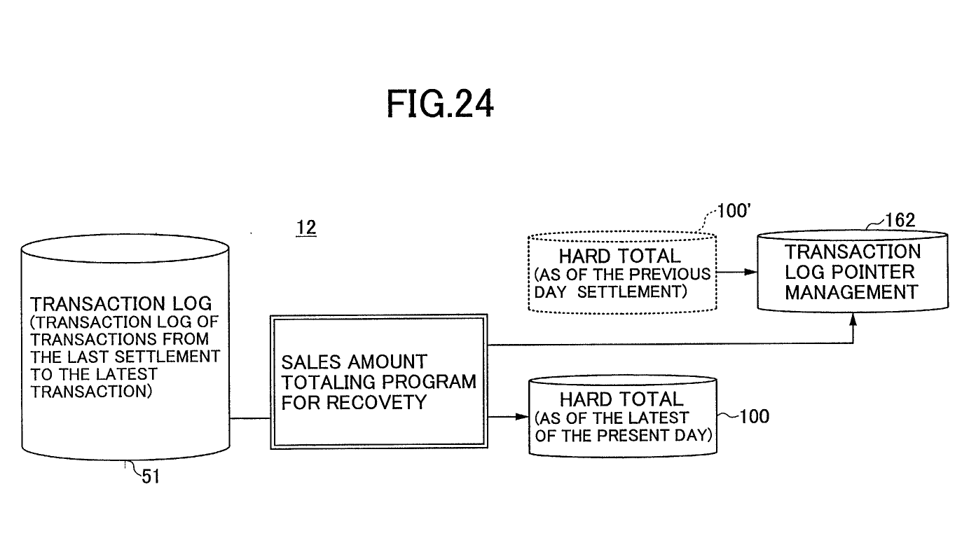

FIG. 23 describes operations of the recovery process of the embodiment of the present invention, and FIG. 24 describes operations of the POS terminal apparatus in the recovery process of the embodiment of the present invention.

In the recovery process that is based on the recovery instruction issued by the operator, the present day transaction log information 51 and the previous day hard total information 100′ stored in the server controller 11 are transmitted from the server controller 11 to the POS terminal apparatus 12. At the POS terminal apparatus 12, the present day transaction log information 51 transmitted from the server controller 11 is stored in the replaced hard drive to recover the present day transaction log information 51, and at the same time, the present day transaction log information 51 stored is sequentially added up to generate the present day hard total information 100.

Further, at this time, the transaction log pointer management information 162 managed by the POS terminal apparatus 12 has also been cleared. For this reason, the transaction serial number and the like of the previous day hard total information 100′ supplied from the server controller 11 are set to the transaction log pointer management information 162 to bring the transaction log pointer management information 162 to the status as of immediately after the settlement of the previous day, and then the present day transaction log information 51 is sequentially added up for updating as shown in FIG. 24. In this manner, the POS terminal apparatus 12 is brought to the status where it was immediately before the fault.

Here, the previous day transaction log information 51′ is not recovered at the POS terminal apparatus 12. This is because the previous day hard total information 100′ has been generated based on the previous day transaction log information 51′ and stored in the server controller 11, which dispenses with the previous day transaction log information 51′, making it unnecessary to be recovered.

As above, by the present embodiment, if the present day transaction log information and the present day hard total information 100 are destroyed due to the fault occurred in the POS terminal apparatus 12, the present day transaction log information 51 and the present day hard total information 100 can be recovered by an easy operation, thereby receiving the present day transaction log information 51 and the previous day hard total information 100′ through demanding a recovery from the POS terminal apparatus 12 to the server controller 11 when the fault is repaired.

As described above, when a fault occurs at the terminal apparatus and a transmission demand for input information is issued from the terminal apparatus, the terminal apparatus can be restored to the status immediately before the fault by providing the terminal apparatus with the input information that has been stored in the upper apparatus every time the information was input to the terminal apparatus and the total information that has been obtained by totaling the input information at a given interval by the terminal apparatus.

1. An information processing method, comprising:
an information inputting step of storing information that is input to a terminal apparatus in said terminal apparatus, and for transmitting and storing said information to and in an upper apparatus that is connected to said terminal apparatus;
an information returning step of transmitting information that has been transmitted to and stored in said upper apparatus by said information transmitting step to said terminal apparatus when said terminal apparatus has a fault; and
a recovering step of restoring said terminal apparatus to a status immediately prior to the fault occurrence based on the information provided from said upper apparatus.

2. The information processing method as claimed in claim 1, further comprising a total information generating step of generating the total information by totaling the information that is input to said terminal apparatus, and wherein said recovering step recovers the input information from the information provided by said upper apparatus, and recovers said total information by totaling said input information.

3. The information processing method as claimed in 2, wherein said total information generating step generates said total information by totaling the information that is input from said terminal apparatus at a predetermined interval.

4. An information processing method, comprising:
a storing step of storing the input information sequentially;
a total information generating step of generating the total information by totaling said input information;
an input information transmitting step of transmitting said input information to the upper apparatus each time the information is input;
a total information transmitting step of transmitting said total information that is generated by said total information generating step at each of predetermined intervals to said upper apparatus;
an input information transmission demanding step of demanding a transmission of said input information of said upper apparatus upon a fault occurrence; and
a recovering step of storing said input information provided from said upper apparatus when said input information is received from said upper apparatus, and for recovering said total information by totaling said input information.

5. An information processing method, comprising:
an input information storing step of storing the input information transmitted from the terminal apparatus;
a total information storing step of storing the total information that is a total of said input information provided from said terminal apparatus at each of predetermined intervals; and
an information transmitting step of transmitting said input information stored in said input information storing step and said total information stored in said total information storing step to said terminal apparatus upon a demand by said terminal apparatus.

6. An information processing apparatus to which information is input and which transmits the input information to an upper apparatus, comprising:
inputting means for inputting information;
total information generating means for generating the total information by totaling said input information that is input by said inputting means;
storing means for storing the input information that is input by said inputting means and storing said total information generated by said total information generating means;
information transmitting means for transmitting the information that is input by said inputting means to an upper apparatus every time the information is input, and transmitting said total information that is generated by said total information generating means at each of predetermined intervals to said upper apparatus;
input information transmission demanding means for demanding a transmission of said input information from said upper apparatus when a fault occurs; and
recovering means for recovering said total information by storing said input information that is input from said upper apparatus in said storing means and by totaling said input information that is input from said information apparatus when said input information is received from said upper apparatus.

7. An information processing apparatus that is connected to a terminal apparatus and manages information input by said terminal apparatus, comprising:
storing means for storing input information that is input at and transmitted from said terminal apparatus, and storing the total information that is a total of said input information and that is transmitted from said terminal apparatus at each of said predetermined intervals; and
information transmitting means for transmitting said input information and said total information stored in said storing means to said terminal apparatus based on a demand from said terminal apparatus.

8. A computer-readable memory medium having a program embodied therein for causing a computer, to which information is input and which provides the input information to an upper apparatus, to execute:
an inputting step of inputting information;
a total information generating step of generating the total information by totaling said input information that is input by said inputting step;
a storing step of storing the input information that is input by said inputting means and storing said total information that is generated by said total information generating means;
an information transmitting step of transmitting information input by said input step to said upper apparatus every time an input is made, and transmitting said total information generated by said total information generating step at each of predetermined intervals to said upper apparatus;
an input information transmission demanding step of demanding of said upper apparatus a transmission of said input information when a fault occurs; and
a recovering step of storing said input information that is input from said upper apparatus to said storing step when said input information is received from said upper apparatus, and for recovering said total information by totaling said input information that is input from said information apparatus.

9. A computer-readable memory medium having a program embodied therein for causing a computer, which is connected to a terminal apparatus and manages information input by said terminal apparatus, to execute:
a storing step of storing the input information that is input at said terminal apparatus and transmitted, and for storing the total information that is transmitted from said terminal apparatus at said predetermined intervals and that is a total of said input information; and
an information transmitting step of transmitting said input information and said total information stored in said storing step to said terminal apparatus based on a demand from said terminal apparatus.
